(19) United States
(12) Patent Application Publication
(10) Pub. No.: US 2025/0098488 A1
(43) Pub. Date: Mar. 20, 2025

(54) DISPLAY DEVICE AND METHOD OF MANUFACTURING THE SAME

(71) Applicant: Samsung Display Co., Ltd., Yongin-si (KR)

(72) Inventors: JUNG-WOO LEE, Yongin-si (KR); WOOYOUNG KIM, Yongin-si (KR)

(73) Assignee: Samsung Display Co., Ltd., Yongin-si (KR)

(21) Appl. No.: 18/769,809

(22) Filed: Jul. 11, 2024

(30) Foreign Application Priority Data
Sep. 19, 2023 (KR) 10-2023-0124883

(51) Int. Cl. H10K 59/80; H10K 59/12; H10K 59/122

(52) U.S. Cl. CPC H10K 59/873; H10K 59/1201; H10K 59/122; H10K 59/8792

(57) ABSTRACT

A display panel includes a light-emitting element disposed on a base substrate and including a light-emitting layer, an inorganic deposition layer disposed on the light-emitting element, and an encapsulation layer disposed on the inorganic deposition layer. The inorganic deposition layer includes a first portion including a first upper surface inclined at a first angle with respect to an upper surface of the base substrate, and a second portion including a second upper surface substantially parallel to the upper surface of the base substrate. A first thickness of the first portion is greater than a second thickness of the second portion. Accordingly, external light reflection may be reduced, and a layer uniformity may be improved, and thus the display device may have improved display efficiency.

### CROSS-REFERENCE TO RELATED APPLICATIONS

This application claims priority to and benefits of Korean Patent Application No. 10-2023-0124883 under 35 U.S.C. § 119, filed in the Korean Intellectual Property Office (KIPO) on Sep. 19, 2023, the entire contents of which are incorporated herein by reference.

### BACKGROUND

### 1. Technical Field

The disclosure relates to a display device having improved display efficiency and a method of manufacturing the same.

### 2. Description of the Related Art

The importance of display devices such as televisions, mobile phones, tablet computers, and game consoles has been emphasized because of the increasing developments of information technology. Each display device may include various optical functional layers and provide a color image of improved quality to a user.

It is desired that the display device is made thin to achieve or improve its flexibility, and has a curved surface, a rollable screen, or a foldable screen. A thin display device may have reduced number of optical functional layers and an optical functional layer having various functions.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device capable of reducing external light reflection and having improved optical property and display efficiency.

Embodiments also provide a method of manufacturing the same capable of improving optical property and display efficiency.

An embodiment of the disclosure provides a display device including a display panel. The display panel includes a light-emitting element disposed on a base substrate and including a light-emitting layer, an inorganic deposition layer disposed on the light-emitting element, and an encapsulation layer disposed on the inorganic deposition layer. The inorganic deposition layer includes a first portion including a first upper surface inclined at a first angle with respect to an upper surface of the base substrate, and a second portion including a second upper surface substantially parallel to the upper surface of the base substrate, and a first thickness of the first portion is greater than a second thickness of the second portion.

In an embodiment, the first angle may be in a range of about 60 degrees to about 90 degrees.

In an embodiment, a surface roughness of the first upper surface may be smaller than a surface roughness of the second upper surface.

In an embodiment, an irregular pattern may be defined on the second upper surface.

In an embodiment, the display panel may further include a pixel-defining film disposed on the base substrate and having a pixel opening, and the light-emitting layer may be disposed in the pixel opening.

In an embodiment, the pixel-defining film may include a side surface defining the pixel opening. The side surface of the pixel-defining film may be inclined at a second angle with respect to the upper surface of the base substrate. The second angle may be substantially the same as the first angle.

In an embodiment, the inorganic deposition layer may include an inorganic material having a refractive index of about 1.0 or greater and a light absorption coefficient of about 0.5 or greater.

In an embodiment, the inorganic deposition layer may include at least one selected from the group consisting of bismuth (Bi) and ytterbium (Yb).

In an embodiment, a difference between the first thickness and the second thickness may be in a range of about 5 Å to about 50 Å.

In an embodiment, the first thickness may be in a range of about 50 Å to about 200 Å.

In an embodiment, the second thickness may be in a range of about 40 Å to about 100 Å.

In an embodiment, the encapsulation layer may be entirely in contact with the first upper surface and the second upper surface.

In an embodiment, the light-emitting element may further include a first electrode disposed on the base substrate, a second electrode spaced apart from the first electrode, a hole transport region disposed between the first electrode and the light-emitting layer, an electron transport region disposed between the second electrode and the light-emitting layer, and a capping layer disposed on the second electrode. The light-emitting layer may be disposed between the first electrode and the second electrode. The inorganic deposition layer may be directly disposed on the capping layer.

In an embodiment, the display device may further include a light control layer disposed on the display panel and including at least one of a dye and a pigment, and a sensor layer disposed between the display panel and the light control layer.

In an embodiment of the disclosure, a display device includes a display panel, and a light control layer disposed on the display panel and including at least one of a dye and a pigment. The display panel includes a light-emitting element disposed on a base substrate and including a light-emitting layer, an inorganic deposition layer disposed on the light-emitting element and including a partition portion and a flat portion adjacent to the partition portion, and an encapsulation layer being entirely in contact with a first upper surface of the partition portion and a second upper surface of the flat portion. The first upper surface is inclined at a first angle with respect to an upper surface of the base substrate, and the second upper surface is substantially parallel to the upper surface of the base substrate. A surface roughness of the first upper surface is smaller than a surface roughness of the second upper surface.

In an embodiment of the disclosure, a method of manufacturing a display device may include providing a base substrate and a light-emitting element including a light-emitting layer disposed on the base substrate, forming, on the light-emitting element, an inorganic deposition layer including an inorganic material, and forming an encapsulation layer on the inorganic deposition layer. The forming of the inorganic deposition layer may include forming a preliminary inorganic deposition layer including a first preliminary portion including a first preliminary upper surface inclined at a first angle with respect to an upper surface of the base substrate, and a second preliminary portion including a second preliminary upper surface substantially parallel to the upper surface of the base substrate, and forming an irregular pattern by etching at least a portion of the second preliminary upper surface.

In an embodiment, the first angle may be in a range of about 60 degrees to about 90 degrees.

In an embodiment, the forming of the preliminary inorganic deposition layer may include performing a thermal evaporation process.

In an embodiment, the forming of the irregular pattern may include performing any one among a wet etching process, a dry etching process, and an ion milling process.

In an embodiment, a thickness of the first preliminary portion and a thickness of the second preliminary portion may be substantially the same.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view of a display device according to an embodiment of the disclosure;

FIG. 2 is a schematic exploded perspective view of a display device according to an embodiment of the disclosure;

FIG. 3 is a schematic plan view of a display device according to an embodiment;

FIG. 4 is a schematic cross-sectional view of a display device according to an embodiment;

FIG. 5 is a schematic enlarged cross-sectional view of a portion of a display device according to an embodiment of the disclosure;

FIGS. 6A and 6B are schematic flowcharts illustrating a method of manufacturing a display device according to an embodiment of the disclosure; and

FIGS. 7A and 7B are schematic drawings sequentially illustrating some operations of a method of manufacturing a display device according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, a display device according to an embodiment of the disclosure will be described with reference to the accompanying drawings.

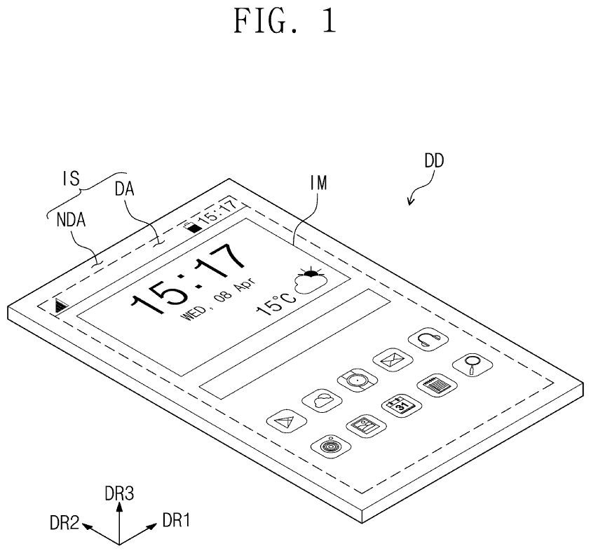

FIG. 1 is a schematic perspective view of a display device according to an embodiment of the disclosure. FIG. 1 illustrates a portable electronic apparatus as an example of a display device DD. However, the display device DD may be used in a large-sized electronic apparatus such as a television, a monitor, a billboard, or the like. For example, the display device DD may be used in a small or medium-sized electronic apparatus such as a personal computer, a laptop, a personal digital assistant, a car navigation part, a game console, a smartphone, a tablet PC, a camera, or the like. However, the disclosure is not limited thereto. The display device DD may also be employed in other electronic apparatuses without departing from the scope of the disclosure.

The display device DD may have a hexahedral shape having a thickness in a third direction DR3 on a plane defined by a first direction DR1 and a second direction DR2 intersecting (e.g., crossing) each other. However, the disclosure is not limited thereto, and the display device DD may have various shapes.

In an embodiment, an upper surface (or a front surface) and a lower surface (or a rear surface) of each member may be defined on the basis of a direction in which an image IM is displayed. The upper surface and the lower surface may be opposite to each other in the third direction DR3, and a normal direction of each of the upper surface and the lower surface may be parallel to the third direction DR3.

Directions indicated by the first to third directions DR1, DR2, and DR3 may be relative, and may be changed into other directions.

The display device DD may display the image IM through a display surface IS. The display surface IS may include a display region DA where the image IM is displayed, and a non-display region NDA adjacent to the display region DA. The non-display region NDA is a region where the image is not displayed. The image IM may be a dynamic image or a still image. FIG. 1 illustrates application icons, a clock, and the like as examples of the image IM.

The display region DA may have a quadrangular shape. The non-display region NDA may be adjacent to (e.g., surround) the display region DA. However, the disclosure is not limited thereto. Thus, a shape of the display region DA and a shape of the non-display region NDA may be relatively designed (or may have various shapes). The non-display region NDA may not exist in a front surface of the display device DD.

The display device DD may be flexible. The flexible display device DD may have a bendable property, and the flexibility of the display device DD may be in a range of a completely foldable structure to a structure bendable to a level of several nanometers. For example, the display device DD may be a curved display device or a foldable display device. However, an embodiment of the disclosure is not limited thereto, and the display device DD may be rigid.

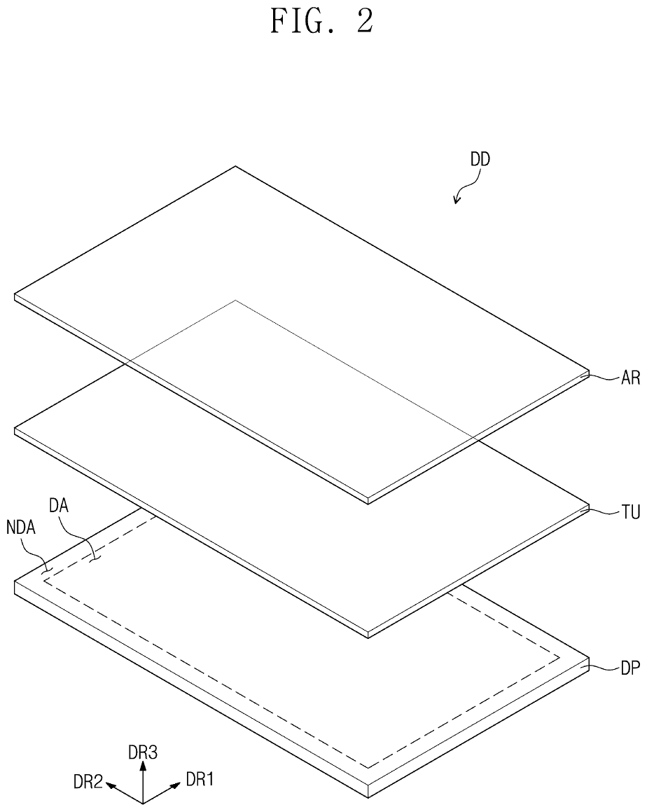

FIG. 2 is a schematic exploded perspective view of a display device according to an embodiment of the disclosure. Referring to FIG. 2, a display device DD according to an embodiment may include a display panel DP, a sensor layer TU, and a light control layer AR, which are sequentially stacked one another in a third direction DR3.

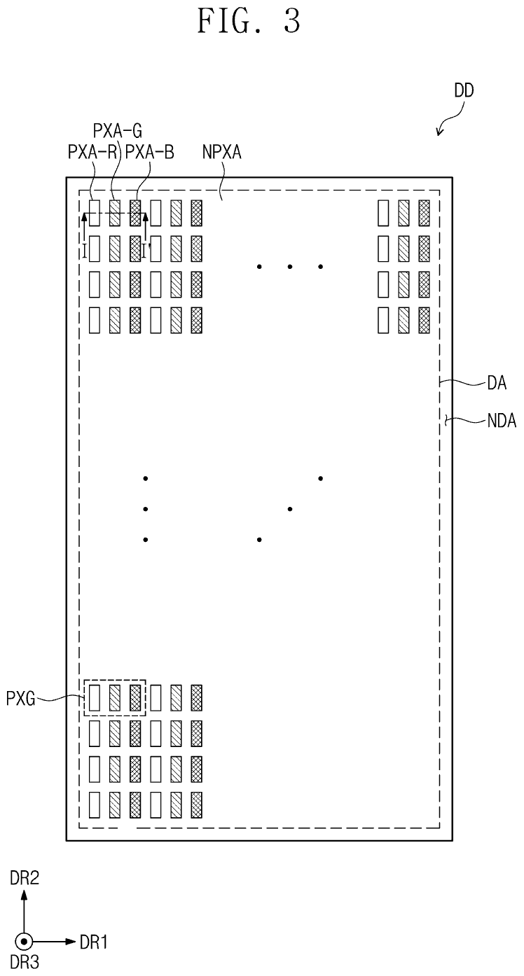

The display panel DP may include pixels in a region (e.g., a display area DA) corresponding to the display device DD. A non-display area NDA may be adjacent to (e.g., may surround) the display area DA. The pixels may correspond to a first pixel region (e.g., a red pixel region) PXA-R, a second pixel region (e.g., a blue pixel region) PXA-B, and a third pixel region (e.g., a green pixel region) PXA-G (e.g., refer to FIG. 3). The pixels may display light in response to an electrical signal. The pixels may generate light and display the image IM in the display region DA.

The display panel DP according to an embodiment may emit light independently. For example, the display panel DP may be a micro-LED display panel, a nano-LED display panel, an organic light-emitting display panel, a quantum dot light-emitting display panel, or the like. However, the disclosure is not limited thereto, and the display panel DP may have various panels emitting light independently.

A light-emitting layer of the organic light-emitting display panel may include an organic light-emitting material. A light-emitting layer of the quantum dot light-emitting display panel may include quantum dots and/or quantum rods, etc. The micro-LED display panel may include a micro-light-emitting diode element that is an ultrasmall light-emitting element, and the nano-LED display panel may include a nano-light-emitting diode element. Hereinafter, the display panel DP is described as an organic light-emitting display panel.

The light control layer AR may be disposed on the display panel DP. The light control layer AR may be an anti-reflective layer which reduces a reflectance for external light incident from the outside. The light control layer AR may be a layer which selectively transmits light emitted from the display panel DP. The light control layer AR may not include a polarizing layer. Accordingly, light passing through the light control layer AR and incident onto the display panel DP and the sensor layer TU may be unpolarized light. The display panel DP and the sensor layer TU may receive unpolarized light from the light control layer AR (e.g., from an upper surface of the light control layer AR).

The sensor layer TU may be disposed between the display panel DP and the light control layer AR. The sensor layer TU may acquire (or sense) an external input to generate information for generating an image on the display panel DP. The external input may be a user's input. The user's input may include various external inputs such as a body part (e.g., a finger, an iris, or the like) of a user, light, heat, a pen, pressure, or the like.

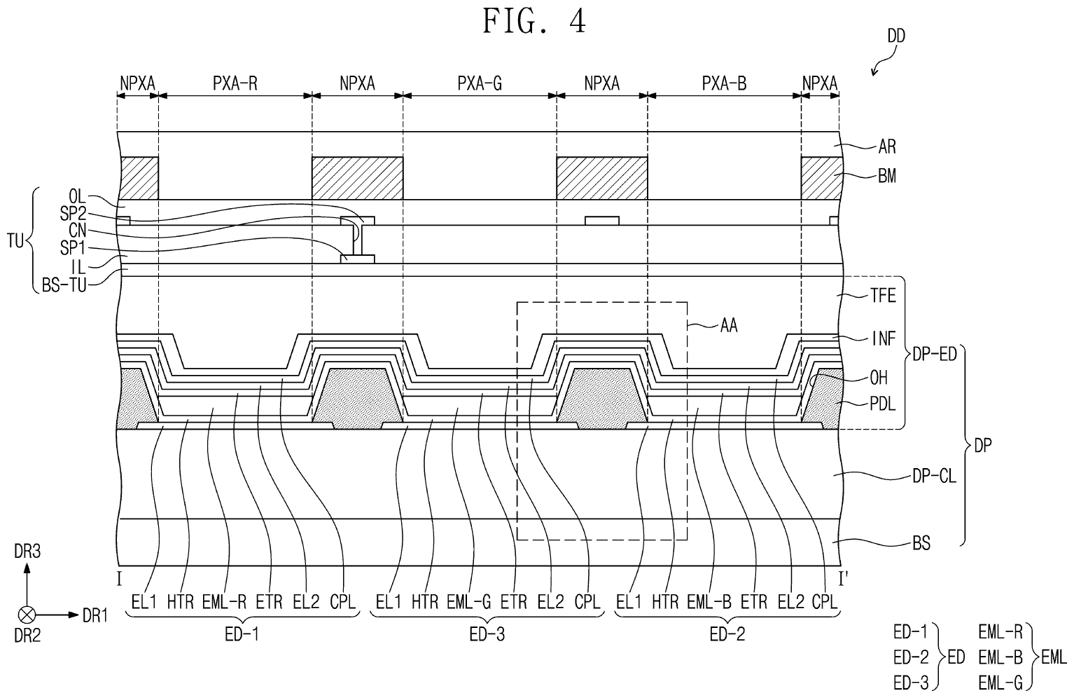

FIG. 3 is a schematic plan view of a display device according to an embodiment. FIG. 4 is a schematic cross-sectional view of a display device according to an embodiment. FIG. 4 is a schematic cross-sectional view of a portion of a display device according to an embodiment taken along line I-I′ of FIG. 3.

Referring to FIGS. 3 and 4, a display device DD according to an embodiment includes a display panel DP, a sensor layer TU disposed on the display panel DP, and a light control layer AR disposed on the sensor layer TU, which are sequentially stacked one another.

The display panel DP may include a base substrate BS, a circuit layer DP-CL, and a display element layer DP-ED, which are sequentially stacked one another. The display element layer DP-ED may include a pixel-defining film PDL, light-emitting elements ED disposed in pixel openings OH defined in the pixel-defining film PDL, and an encapsulation layer TFE disposed on the light-emitting elements ED.

The base substrate BS may be rigid or flexible. The base substrate BS may be a polymer substrate, a plastic substrate, a glass substrate, a metal substrate, a composite material substrate, or the like. The base substrate BS may have a multi-layered structure. In other embodiments, the base substrate BS may have a single-layered structure. The base substrate BS may include a synthetic resin film, and the base substrate BS may have a multi-layered structure including synthetic resin film layers. The synthetic resin film of the base substrate BS may include at least one of a polyimide-based material, an acrylate-based material, a vinyl-based material, an epoxy-based material, a urethane-based material, a cellulose-based material, and a perylene-based material. However, the disclosure is not limited thereto, and the synthetic resin film may have various materials.

The circuit layer DP-CL may be disposed on the base substrate BS. The circuit layer DP-CL may include an insulating layer, a semiconductor pattern, a conductive pattern, a signal line, and the like. The circuit layer DP-CL may include transistors (not illustrated) formed of a semiconductor pattern, a conductive pattern, a signal line, and the like. Each of the transistors (not illustrated) may include a control electrode, an input electrode, and an output electrode. For example, the circuit layer DP-CL may include a driving transistor and a switching transistor for driving the light-emitting elements ED.

The display element layer DP-ED may be disposed on the circuit layer DP-CL. The display element layer DP-ED may include the pixel-defining film PDL, the light-emitting elements ED, and the encapsulation layer TFE.

The light-emitting elements ED may include a first light-emitting element ED-1, a second light-emitting element ED-2, and a third light-emitting element ED-3. Each of the first to third light-emitting elements ED-1, ED-2, and ED-3 may include a first electrode EL1, a hole transport region HTR, an electron transport region ETR, a second electrode EL2, and a capping layer CPL. The first to third light-emitting elements ED-1, ED-2, and ED-3 may respectively include a first light-emitting layer EML-R, a second light-emitting layer EML-B, and a third light-emitting layer EML-G. The first light-emitting element ED-1 may include the first light-emitting layer EML-R overlapping a first pixel region PXA-R in a plan view. The second light-emitting element ED-2 may include the second light-emitting layer EML-B overlapping a second pixel region PXA-B in a plan view. The third light-emitting element ED-3 may include the third light-emitting layer EML-G overlapping a third pixel region PXA-G in a plan view.

The pixel-defining film PDL may be disposed on the circuit layer DP-CL. Pixel openings (e.g., predetermined or selected pixel openings) OH may be defined in the pixel-defining film PDL. The pixel openings OH defined in the pixel-defining film PDL may respectively correspond to the first to third pixel regions PXA-R, PXA-B, and PXA-G. A light-shielding region NPXA may be a region between adjacent ones of the first to third pixel regions PXA-R, PXA-B, and PXA-G and may be a region corresponding to the pixel-defining film PDL.

The pixel-defining film PDL may absorb light (e.g., may have a light-absorbing property). For example, the pixel-defining film PDL may have a black color. The pixel-defining film PDL may include a black coloring agent. The black coloring agent may include a black dye or a black pigment. The black coloring agent may include carbon black, metal such as chromium, or oxides thereof. The pixel-defining film PDL may correspond to a light-shielding pattern having a light-shielding property.

The pixel-defining film PDL may include an organic resin or an inorganic material. For example, the pixel-defining film PDL may be formed of at least one material including a polyacrylate-based resin, a polyimide-based resin, or silicon nitride (SiNₓ), silicon oxide (SiOₓ), and silicon oxynitride (SiOₓN_{y}). However, the disclosure is not limited thereto, and the pixel-defining film PDL may include various materials.

In FIG. 4, the first to third light-emitting layers EML-R, EML-B, and EML-G of the first to third light-emitting elements ED-1, ED-2, and ED-3 may be disposed in the pixel openings OH defined in the pixel-defining film PDL. The hole transport region HTR, the electron transport region ETR, the second electrode EL2, and the capping layer CPL may be provided as common layers in all of the first to third light-emitting elements ED-1, ED-2, and ED-3. However, an embodiment of the disclosure is not limited thereto, and in an embodiment, unlike what is illustrated in FIG. 4, the hole transport region HTR, the electron transport region ETR, the second electrode EL2, the capping layer CPL, etc., may be patterned in a pixel opening OH defined in the pixel-defining film PDL. In an embodiment, at least one of the hole transport region HTR, the electron transport region ETR, the second electrode EL2, the capping layer CPL, and the first to third light-emitting layers EML-R, EML-B, and EML-G of the first to third light-emitting elements ED-1, ED-2 or ED-3 may be patterned through an inkjet printing method.

In each light-emitting element ED, the first electrode EL1 may be disposed on the circuit layer DP-CL. The first electrode EL1 may be an anode or a cathode. The first electrode EL1 may be a pixel electrode. The first electrode EL1 may be a transmissive electrode, a transflective electrode, or a reflective electrode.

The hole transport region HTR may be disposed between the first electrode EL1 and a light-emitting layer EML. The hole transport region HTR may include at least one of a hole injection layer, a hole transport layer, and an electron blocking layer. The hole transport region HTR may be disposed as a common layer and overlap (e.g., entirely overlap) the first to third pixel regions PXA-R, PXA-B, and PXA-G and the pixel-defining film PDL in a plan view. The pixel-defining film PDL may separate the first to third pixel regions PXA-R, PXA-B, and PXA-G in a plan view. For example, the pixel-defining film PDL may be disposed between adjacent ones of the first to third pixel regions PXA-R, PXA-B, and PXA-G. However, an embodiment of the disclosure is not limited thereto, and the hole transport region HTR may be provided through patterning and patterned hole transport regions may be separately disposed to respectively correspond to the first to third pixel regions PXA-R, PXA-B, and PXA-G.

The light-emitting layer EML may be disposed on the first electrode EL1. The light-emitting layer EML may include the first to third light-emitting layers EML-R, EML-B, and EML-G. The first light-emitting layer EML-R may overlap the first pixel region PXA-R in a plan view and emit a first light. The second light-emitting layer EML-B may overlap the second pixel region PXA-B in a plan view and emit a second light. The third light-emitting layer EML-G may overlap the third pixel region PXA-G in a plan view and emit a third light. In the first to third light-emitting elements ED-1, ED-2, and ED-3 according to an embodiment, the first to third light may be in substantially different wavelength ranges from one another. For example, the first light may be red light in a wavelength range of about 625 nm to about 675 nm. For example, the second light may be blue light in a wavelength range of about 410 nm to about 480 nm. The third light may be green light in a wavelength range of about 500 nm to about 570 nm.

The electron transport region ETR may be disposed between the light-emitting layer EML and the second electrode EL2. The electron transport region ETR may include at least one of an electron injection layer, an electron transport layer, and a hole blocking layer. The electron transport region ETR may be disposed as a common layer and overlap (e.g., entirely overlap) the first to third pixel regions PXA-R, PXA-B, and PXA-G and the pixel-defining film PDL in a plan view. The pixel-defining film PDL may separate the first to third pixel regions PXA-R, PXA-B, and PXA-G. For example, the pixel-defining film PDL may be disposed between adjacent ones of the first to third pixel regions PXA-R, PXA-B, and PXA-G. However, an embodiment of the disclosure is not limited thereto, and the electron transport region ETR may be provided through patterning and patterned electron transport regions may be separately disposed to respectively correspond to the first to third pixel regions PXA-R, PXA-B, and PXA-G.

The second electrode EL2 is provided on the electron transport region ETR. The second electrode EL2 may be a common electrode. The second electrode EL2 may be a cathode or an anode, but an embodiment of the disclosure is not limited thereto. For example, in case that the first electrode EL1 is an anode, the second electrode EL2 may be a cathode, and in case that the first electrode EL1 is a cathode, the second electrode EL2 may be an anode. The second electrode EL2 may be a transmissive electrode, a transflective electrode, or a reflective electrode.

The capping layer CPL may be further disposed on the second electrode EL2. The capping layer CPL may include layers or a single layer. In an embodiment, the capping layer CPL may be an organic layer or an inorganic layer. For example, in case that the capping layer CPL includes an inorganic material, the inorganic material may include an alkali metal compound such as LiF, an alkaline earth metal compound such as MgF₂, SiON, SiNₓ, SiO_{y}, etc. For example, in case that the capping layer CPL includes an organic material, the organic material may include α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-tris (carbazol-9-yl) triphenylamine (TCTA), etc., or include an epoxy resin, or acrylate such as methacrylate. However, an embodiment of the disclosure is not limited thereto.

A refractive index of the capping layer CPL may be about 1.6 or greater. For example, a refractive index of the capping layer CPL with respect to light in a wavelength range of about 550 nm to about 660 nm may be about 1.6 or greater.

The encapsulation layer TFE may be disposed on the pixel-defining film PDL and cover the light-emitting element ED. The encapsulation layer TFE may fill a portion of the pixel opening OH and may be disposed on the capping layer CPL. As illustrated in FIG. 4, in case that the light-emitting element ED includes an inorganic deposition layer INF, the encapsulation layer TFE may be disposed on the inorganic deposition layer INF. The encapsulation layer TFE may serve as protecting the light-emitting element ED from moisture and/or oxygen and protecting the light-emitting element ED from foreign substances such as dust particles.

FIG. 4 illustrates the encapsulation layer TFE as a single layer, but the encapsulation layer TFE may include at least one organic film or inorganic film, or include both of an organic film and an inorganic film. The encapsulation layer TFE may have a thin-film encapsulation layer structure including at least one organic film and at least one inorganic film. For example, the encapsulation layer TFE may have a structure in which an organic film and an inorganic film are alternately and repeatedly stacked each other, or a structure in which an inorganic film, an organic film, and an inorganic film are sequentially stacked one another.

The inorganic film included in the encapsulation layer TFE may include, for example, a silicon nitride layer, a silicon oxynitride layer, a silicon oxide layer, a titanium oxide layer, an aluminum oxide layer, or the like, but an embodiment of the disclosure is not limited thereto. The organic film included in the encapsulation layer TFE may include an acrylate-based organic film, but an embodiment of the disclosure is not limited thereto.

The display device DD may include the light-shielding region NPXA and the first to third pixel regions PXA-R, PXA-B, and PXA-G. The first to third pixel regions PXA-R, PXA-B, and PXA-G may be regions respectively emitting light generated from the first to third light-emitting elements ED-1, ED-2, and ED-3. The first to third pixel regions PXA-R, PXA-B, and PXA-G may be spaced apart from each other in a plan view.

The first to third pixel regions PXA-R, PXA-B, and PXA-G may each be separated by the pixel-defining film PDL. For example, the pixel-defining film PDL may be disposed between adjacent ones of the first to third pixel regions PXA-R, PXA-B, and PXA-G. The light-shielding region NPXA may be a region between adjacent ones of the first to third pixel regions PXA-R, PXA-B, and PXA-G and may be a region corresponding to the pixel-defining film PDL. For example, each of the first to third pixel regions PXA-R, PXA-B, and PXA-G may correspond to a pixel. The pixel-defining film PDL may separate the first to third light-emitting elements ED-1, ED-2, and ED-3. For example, the pixel-defining film PDL may be disposed between adjacent ones of the first to third light-emitting elements ED-1, ED-2, and ED-3. The first to third light-emitting layers EML-R, EML-B, and EML-G of the first to third light-emitting elements ED-1, ED-2, and ED-3 may be separately disposed in the pixel openings OH defined in the pixel-defining film PDL. For example, the first to third light-emitting layers EML-R, EML-B, and EML-G of the first to third light-emitting elements ED-1, ED-2, and ED-3 may be spaced apart from each other.

The first to third pixel regions PXA-R, PXA-B, and PXA-G may be divided into groups according to a color of light generated from the first to third light-emitting elements ED-1, ED-2, and ED-3. In the display device DD illustrated in FIGS. 3 and 4, three pixel regions PXA-R, PXA-B, and PXA-G respectively may emit red light, blue light, and green light. For example, the display device DD according to an embodiment may include the first pixel region PXA-R, the second pixel region PXA-B, and the third pixel region PXA-G, which are distinguished from each other (or are spaced apart from each other). In an embodiment, the first pixel region PXA-R may be referred to as a red pixel region, the second pixel region PXA-B may be referred to as a blue pixel region, and the third pixel region PXA-G may be referred to as a green pixel region. In the display device DD according to an embodiment, a first pixel region PXA-R, a second pixel region PXA-B, and a third pixel region PXA-G may be grouped and referred to as a pixel group PXG. Although not illustrated, at least one of the first pixel region PXA-R, the second pixel region PXA-B, and the third pixel region PXA-G, included in the pixel group PXG, may be provided in plurality. For example, the number of the first pixel region PXA-R, the second pixel region PXA-B, and the third pixel region PXA-G in each pixel group PXG may be two or more. For example, two third pixel regions PXA-G, a first pixel region PXA-R, and a second pixel region PXA-B may be included in the pixel group PXG.

In the display device DD according to an embodiment, the first to third light-emitting elements ED-1, ED-2, and ED-3 may emit light in different wavelength ranges. For example, the display device DD according to an embodiment may include the first light-emitting element ED-1 emitting red light, the second light-emitting element ED-2 emitting blue light, and the third light-emitting element ED-3 emitting green light. For example, the red pixel region PXA-R, the blue pixel region PXA-B, and the green pixel region PXA-G of the display device DD may respectively correspond to the first light-emitting element ED-1, the second light-emitting element ED-2, and the third light-emitting element ED-3.

However, an embodiment of the disclosure is not limited thereto, and the first to third light-emitting elements ED-1, ED-2, and ED-3 may emit light in a same wavelength range. In other embodiments, at least one of the first to third light-emitting elements ED-1, ED-2, and ED-3 may emit light in a wavelength range different from others of the first to third light-emitting elements ED-1, ED-2, and ED-3. In other embodiments, all of the first to third light-emitting elements ED-1, ED-2, and ED-3 may emit blue light.

In the display device DD according to an embodiment, the first to third pixel regions PXA-R, PXA-B, and PXA-G may be arranged in a stripe shape. Referring to FIG. 3, red pixel regions (e.g., first pixel regions) PXA-R, blue pixel regions (e.g., second pixel regions) PXA-B, and green pixel regions (e.g., third pixel regions) PXA-G may each be arrayed (or arranged) in a second direction DR2. The red pixel region PXA-R, the green pixel region PXA-G, and the blue pixel region PXA-B may be alternately and repeatedly arranged in an order (e.g., a predetermined or selected order) in a first direction DR1.

In FIGS. 3 and 4, all the first to third pixel regions PXA-R, PXA-B, and PXA-G may have similar areas. However, an embodiment of the disclosure is not limited thereto. Thus, areas of the first to third pixel regions PXA-R, PXA-B, and PXA-G may vary depending on a wavelength range of the emitted light. The areas of the first to third pixel regions PXA-R, PXA-B, and PXA-G may be defined by the first direction DR1 and the second direction DR2 in a plan view.

An arrangement of the first to third pixel regions PXA-R, PXA-B, and PXA-G is not limited to that illustrated in FIG. 3, and the red pixel region PXA-R, the blue pixel region PXA-B, and the green pixel region PXA-G may have various arrangements (e.g., combinations) according to the characteristics of display quality required for the display device DD. For example, the first to third pixel regions PXA-R, PXA-B, and PXA-G may be arranged in a PenTile™ shape or a Diamond Pixel™ shape.

The areas of the first to third pixel regions PXA-R, PXA-B, and PXA-G may be different from each other. For example, in an embodiment, an area of the green pixel region PXA-G may be smaller than an area of the blue pixel region PXA-B. However, an embodiment of the disclosure is not limited thereto.

Referring to FIG. 4, the display panel DP according to an embodiment may include the inorganic deposition layer INF disposed on the first to third light-emitting elements ED-1, ED-2, and ED-3.

The inorganic deposition layer INF may be disposed on the capping layer CPL. The inorganic deposition layer INF may be disposed on (e.g., be directly disposed on) the capping layer CPL. The inorganic deposition layer INF may be a layer for preventing external light from being reflected by the second electrode EL2 of the first to third light-emitting elements ED-1, ED-2, and ED-3. For example, destructive interference may occur between light reflected at a surface of the inorganic deposition layer INF and light reflected at the second electrode EL2. Thus, the amount of external light reflected at a surface of the second electrode EL2 may be reduced (or canceled out). Thicknesses of the inorganic deposition layer INF and the capping layer CPL may be adjusted and destructive interference may occur between light reflected at a surface of the inorganic deposition layer INF and light reflected at the second electrode EL2.

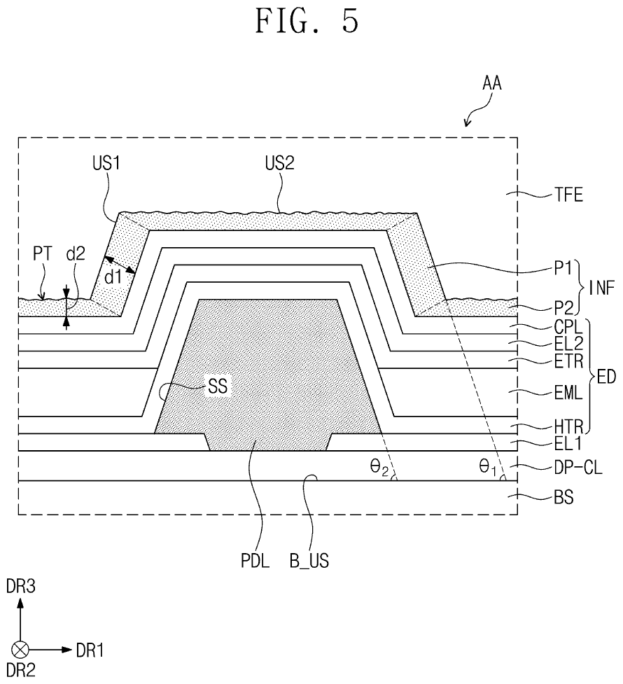

The inorganic deposition layer INF may include an inorganic material having a refractive index of about 1.0 or greater and a light absorption coefficient of about 0.5 or greater. With respect to a visible light wavelength range of about 380 nm to about 780 nm, the inorganic material included in the inorganic deposition layer INF may have a refractive index of about 1.0 or greater and a light absorption coefficient of about 0.5 or greater. The inorganic deposition layer INF may be formed through a thermal evaporation process and include an inorganic material having a melting point of about 1,000° C. or smaller. The inorganic deposition layer INF may include, for example, at least one selected from the group consisting of bismuth (Bi) and ytterbium (Yb). A material forming the inorganic deposition layer INF may be composed of bismuth (Bi) or ytterbium (Yb). In other embodiments, the inorganic deposition layer INF may include a YbₓBi_{y}-mixed deposition material. The encapsulation layer TFE may be disposed on (e.g., be directly disposed on) at least a portion of the inorganic deposition layer INF. Detailed description regarding the inorganic deposition layer INF is provided below with reference to FIG. 5.

In the display device DD according to an embodiment, the light control layer AR may be disposed on the display panel DP. The light control layer AR may absorb portion of light emitted from the display panel DP and transmit portion of the light. Thus, color gamut of the display device DD may be improved. As used herein, the term “color gamut” refers to a range of colors that are displayable by a display device. For example, color gamut may be improved by selective absorption of light in a wavelength range (e.g., a specific or selectable wavelength range).

The light control layer AR may overlap (e.g., entirely overlap) the display element layer DP-ED in a plan view. The light control layer AR may overlap (e.g., entirely overlap) each of the first light-emitting element ED-1, the second light-emitting element ED-2, and the third light-emitting element ED-3 in a plan view. The light control layer AR may cover a front surface of the display panel DP and protect the display panel DP.

The light control layer AR may have a high light absorption rate in a wavelength range (e.g., a specific or selectable wavelength range). The light control layer AR may include a first colorant having a high light absorption rate in a wavelength range (e.g., a specific or selectable wavelength range). The first colorant may have a high light absorption rate in a wavelength range (e.g., a specific or selectable wavelength range). The first colorant may have a high light absorption rate in at least one wavelength range. The first colorant may absorb light having a maximum absorption wavelength in a wavelength range except wavelength ranges of the first light, the second light, and the third light. In an embodiment, the first colorant may absorb light in a wavelength range of about 490 nm to about 505 nm and light in a wavelength range of about 585 nm to about 600 nm, and transmit the remaining light. The first colorant may have a maximum absorption wavelength in a wavelength range of about 490 nm to about 505 nm and in a wavelength range of about 585 nm to about 600 nm. The first colorant included in the light control layer AR may absorb light in a wavelength range (e.g., a specific or selectable wavelength range) and transmit light in the remaining wavelength range. Thus, external light reflection may be prevented and a color tone of light emitted from the display panel DP may be adjusted.

The first colorant may include at least one of a dye and a pigment. For example, the first colorant included in the light control layer AR may include at least one selected from the group consisting of an anthraquinone-based compound, a phthalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squarylium-based compound, an oxazine-based compound, a triarylmethane-based compound, and a cyanine-based compound. For example, the light control layer AR may include at least one of a tetraazaporphyrin-based compound, a cyanine-based compound, a squarylium-based compound, and an oxazine-based compound. However, the disclosure is not limited thereto, and the light control layer AR may include various materials.

The light control layer AR may include about 0.01 wt % to about 5.00 wt % of the first colorant with respect to a total weight of the light control layer AR. In case that the light control layer AR includes less than about 0.01 wt % of the first colorant, light in a wavelength range (e.g., a specific or selectable wavelength range) may not be sufficiently absorbed, and color gamut may not be improved. In case that the light control layer AR includes more than about 5.00 wt % of the first colorant, cohesion of the first colorant may occur.

In an embodiment, the display device DD may further include light-shielding portions BM disposed on the display element layer DP-ED. The light-shielding portions BM may be covered by the light control layer AR and overlap the light-shielding region NPXA in a plan view. The light-shielding portions BM may be spaced apart from each other. The light-shielding portions BM may prevent a light leakage phenomenon. The light-shielding portions BM may be light-shielding members (e.g., black matrix). The light-shielding portions BM may include an organic light-shielding material, a black dye, a black pigment, or the like. The light control layer AR may fill a gap between the light-shielding portions BM spaced apart from each other.

The sensor layer TU may be disposed between the display panel DP and the light control layer AR. The sensor layer TU may include a sensor base layer BS-TU, a first conductive layer SP1, an inorganic insulating layer IL, a second conductive layer SP2, and an organic insulating layer OL. The first conductive layer SP1 may be disposed on the sensor base layer BS-TU. The inorganic insulating layer IL may cover the first conductive layer SP1 and may be disposed on the sensor base layer BS-TU and the first conductive layer SP1. The second conductive layer SP2 may be disposed on the inorganic insulating layer IL. The organic insulating layer OL may cover the second conductive layer SP2 and may be disposed on the inorganic insulating layer IL and the second conductive layer SP2.

The sensor base layer BS-TU may be an inorganic layer including at least one of silicon nitride, silicon oxynitride, and silicon oxide. In other embodiments, the sensor base layer BS-TU may be an organic layer including at least one of an epoxy resin, an acryl resin, and an imide-based resin. However, the disclosure is not limited thereto, and the sensor base layer BS-TU may include various materials. The sensor base layer BS-TU may have a single-layered structure or a multi-layered structure in which layers are stacked each other in a third direction DR3. The sensor base layer BS-TU may be disposed on (e.g., directly disposed on) the encapsulation layer TFE.

Each of the first conductive layer SP1 and the second conductive layer SP2 may have a single-layered structure or a multi-layered structure in which layers are stacked each other in the third direction DR3. In case that each of the first and second conductive layers SP1 and SP2 has a single-layered structure, each of the first and second conductive layers SP1 and SP2 may include a metal layer or a transparent conductive layer. The metal layer may include at least one of molybdenum, silver, titanium, copper, and aluminum. In other embodiments, the metal layer may include a combination or an alloy thereof. The transparent conductive layer may include at least one transparent conductive oxide of indium tin oxide (ITO), indium zinc oxide (IZO), zinc oxide (ZnO), and indium zinc tin oxide (IZTO). The transparent conductive layer may include a conductive polymer such as PEDOT, a metal nanowire, graphene, etc. However, the disclosure is not limited thereto, and the first and second conductive layers SP1 and SP2 may have various materials.

Each of the first and second conductive layers SP1 and SP2 may have a multi-layered structure including metal layers. For example, the metal layers may have a three-layered structure of titanium (Ti)/aluminum (Al)/titanium (Ti). Each of the first and second conductive layers SP1 and SP2 may have a multi-layered structure including at least one metal layer and at least one transparent conductive layer.

The inorganic insulating layer IL may include at least one of aluminum oxide, titanium oxide, silicon oxide, silicon oxynitride, zirconium oxide, and hafnium oxide. However, the disclosure is not limited thereto.

A contact hole CN may be defined in the inorganic insulating layer IL. The first conductive layer SP1 and the second conductive layer SP2 may be electrically connected to each other through the contact hole CN. The contact hole CN may be filled with a material of the second conductive layer SP2. FIG. 4 illustrates that a single contact hole CN is defined in the inorganic insulating layer IL. However, an embodiment of the disclosure is not limited thereto, and multiple contact holes may be defined in the inorganic insulating layer IL.

The organic insulating layer OL may cover the inorganic insulating layer IL and the second conductive layer SP2. The organic insulating layer OL may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin. However, the disclosure is not limited thereto, and the organic insulating layer OL may include various materials.

FIG. 5 is a schematic enlarged cross-sectional view of a portion of a display device according to an embodiment of the disclosure. FIG. 5 illustrates an enlarged cross section corresponding to an AA region of FIG. 4 so as to more specifically illustrate a shape in which the inorganic deposition layer INF is disposed on the light-emitting element ED. Detailed description of the inorganic deposition layer INF of the disclosure is provided below with reference to FIG. 5. The detailed description of the same constituent elements is omitted.

The inorganic deposition layer INF may include a first portion P1 and a second portion P2. The first portion P1 may be defined as a portion including a first upper surface US1, and the second portion P2 may be defined as a portion including a second upper surface US2. In the inorganic deposition layer INF, each of the first upper surface US1 and the second upper surface US2 may refer to a surface in contact with the encapsulation layer TFE. For example, the first upper surface US1 may be disposed on an interface between the first portion P1 and the encapsulation layer TFE, and the second upper surface US2 may be disposed on an interface between the second portion P2 and the encapsulation layer TFE. As used herein, the first portion P1 may be referred to as a “partition portion”, and the second portion P2 may be referred to as a “flat portion”.

The first upper surface US1 of the first portion P1 may refer to a flat surface inclined at a first angle θ1 with respect to an upper surface B_US of the base substrate BS. The first angle θ1 may refer to an angle formed by the first upper surface US1 and the upper surface B_US of the base substrate BS. The first angle θ1 may be in a range of about 60 degrees to about 90 degrees. For example, the first angle θ1 may be in a range of about 65 degrees to about 85 degrees. A normal direction of the first upper surface US1 may not be parallel to a third direction DR3.

The first portion P1 may correspond to a side surface SS of the pixel-defining film PDL. The first portion P1 may be a portion disposed on some of the light-emitting elements ED disposed on the side surface SS of the pixel-defining film PDL. The side surface SS of the pixel-defining film PDL may refer to a surface defining the pixel opening OH (e.g., refer to FIG. 4). The first upper surface US1 of the first portion P1 may be substantially parallel to the side surface SS of the pixel-defining film PDL. The first angle θ1 formed by the upper surface B_US of the base substrate BS may be inclined at the first angle θ1 with respect to the first upper surface US1. The upper surface B_US of the base substrate BS may be inclined at the second angle θ2 with respect to the side surface SS of the pixel-defining film PDL. The first upper surface US1 may be substantially the same as the second angle θ2. As used herein, the wording, “substantially parallel” includes not only a case in which two surfaces do not meet each other no matter how long the surfaces extend, but also a case in which, despite two surfaces parallel to (e.g., designed to be parallel to) each other, there is a difference in distance between the two surfaces which falls within a margin of error (or an acceptable manufacturing tolerance) in a process. The wording, “substantially the same” includes not only a case in which components have the same thickness (e.g., physically completely the same thickness, etc.), but also a case in which, despite the same design of components, there is a difference in thickness, etc., therebetween which falls within a margin of error in a process.

The second upper surface US2 may be substantially parallel to the upper surface B_US of the base substrate BS. Each of the second upper surface US2 and the upper surface B_US of the base substrate BS may be parallel to a plane defined by a first direction DR1 and a second direction DR2 intersecting (e.g., crossing) each other. Accordingly, a normal direction of each of the second upper surface US2 and the upper surface B_US of the base substrate BS may be parallel to the third direction DR3.

A first thickness d1 of the first portion P1 may be greater than a second thickness d2 of the second portion P2. The first thickness d1 may be a shortest distance between the first upper surface US1 and the light-emitting element ED. For example, the first thickness d1 may be a perpendicular distance from an upper surface of the capping layer CPL in the light-emitting element ED to the first upper surface US1. As used herein, the term “perpendicular distance” may be a shortest distance measured in a normal direction (e.g., in a direction perpendicular to a tangent line) at a measuring point. The second thickness d2 may be a shortest distance between the second upper surface US2 and the light-emitting element ED. For example, the second thickness d2 may be a distance from an upper surface of the capping layer CPL in the light-emitting element ED to the second upper surface US2 in the third direction DR3. A difference between the first thickness d1 and the second thickness d2 may be in a range of about 5 Å to about 50 Å. For example, the first thickness d1 may be in a range of about 50 Å to about 200 Å, and the second thickness d2 may be in a range of about 40 Å to about 100 Å. In case that the first thickness d1 of the first portion P1 is less than about 50 Å, layer uniformity of the inorganic deposition layer INF including the first portion P1 may be reduced. In an embodiment, in case that the first portion P1 is composed of a bismuth (Bi) (e.g., a bismuth (Bi) based material), the first thickness d1 may be desirably about 100 Å. In case that the first portion P1 is composed of bismuth (Bi) and the first thickness d1 is about 100 Å, layer uniformity of the inorganic deposition layer INF including the first portion P1 may be secured. In an embodiment, in case that the first portion P1 includes a YbₓBi_{y}-mixed deposition material, the first thickness d1 may be in a range of about 50 Å to about 70 Å. In case that the first portion P1 is composed of a YbₓBi_{y}-mixed deposition material and the first thickness d1 is in a range of about 50 Å to about 70 Å, layer uniformity of the inorganic deposition layer INF including the first portion P1 may be secured. In case that the second thickness d2 of the second portion P2 is more than about 100 Å, an external light reflectance of the display device DD (e.g., refer to FIG. 4) including the second portion P2 may increase, and light emission efficiency may be reduced.

A surface roughness of the first upper surface US1 of the first portion P1 may be smaller than a surface roughness of the second upper surface US2 of the second portion P2. The second upper surface US2 may include an irregular pattern PT, and the first upper surface US1 may not include the irregular pattern PT. The irregular pattern PT may be formed by etching at least a portion of the second portion P2 through an etching process.

According to an embodiment of the disclosure, a display device may include a portion having a non-uniform thickness in an inorganic deposition layer. In the inorganic deposition layer, a flat portion arranged in parallel to a base substrate, etc., may have a relatively thin structure, and a partition portion having an inclination (e.g., a specific or selectable inclination) due to an opening in which a pixel is defined may have a relatively thick structure. For example, the flat portion arranged in parallel to the base substrate may have a smaller thickness than that of the partition portion having the inclination. Accordingly, a display device according to an embodiment of the disclosure may have an improved light efficiency and reduced external light reflection. For example, since the flat portion is relatively thin in the inorganic deposition layer, external light reflection may be reduced, and effectiveness of light transmittance may be improved. Since the partition portion is relatively thick in the inorganic deposition layer, layer uniformity may be secured, and light emission efficiency may increase. Accordingly, a display device may have improved reliability and an increased manufacturing efficiency. Since the flat portion (e.g., the second portion P2) may have an irregular pattern on the upper surface (e.g., the second upper surface US2) of the flat portion and have a relatively high surface roughness, compared to the partition portion (e.g., the first portion P1), a display device may have a reduced white angular dependency (WAD) property. Therefore, a display device according to an embodiment of the disclosure may include the inorganic deposition layer including the flat portion (e.g., the second portion P2) and the partition portion (e.g., the first portion P1). Thus, reliability and a light emitting property may be improved.

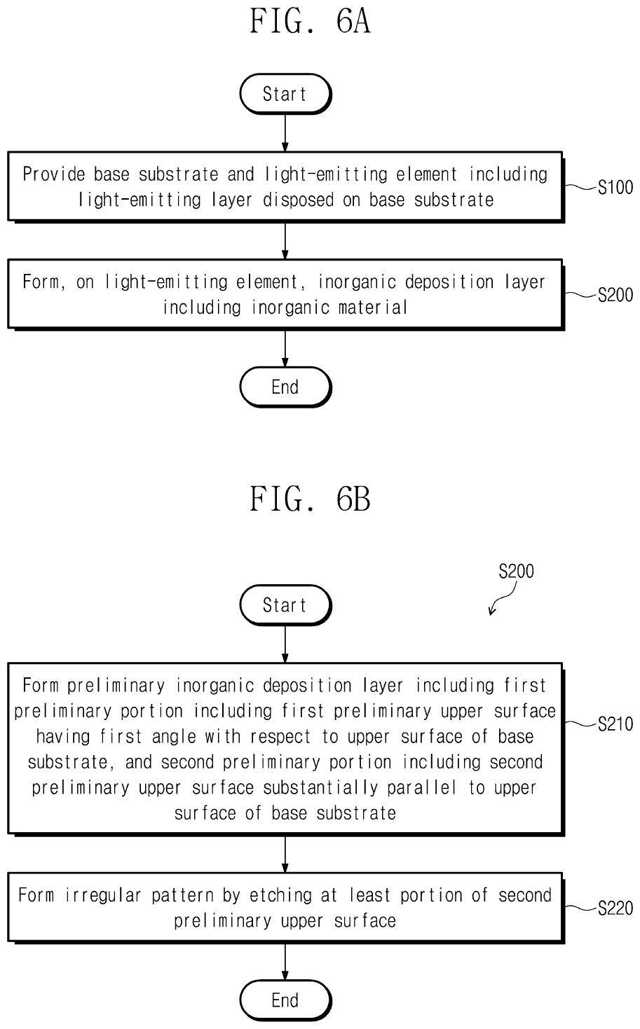

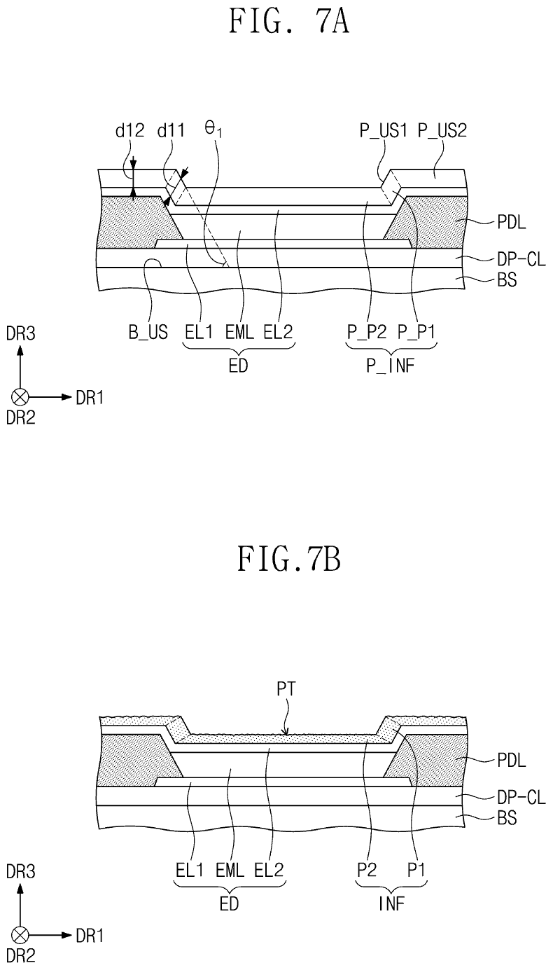

Detailed description of a method of manufacturing a display device according to an embodiment of the disclosure is provided below with reference to FIGS. 6A, 6B, 7A, and 7B.

FIG. 6A is a schematic flowchart illustrating a method of manufacturing a display device according to an embodiment of the disclosure. FIG. 6B is a schematic flowchart illustrating forming an inorganic deposition layer in a method of manufacturing a display device according to an embodiment of the disclosure. FIGS. 7A and 7B are schematic drawings sequentially illustrating some operations in a method of manufacturing a display device according to an embodiment of the disclosure. In description of a method of manufacturing a display device according to an embodiment of the disclosure, detailed description of the same constituent elements is omitted.

Referring to FIGS. 6A and 7A, a method of manufacturing a display device according to an embodiment of the disclosure may include providing a base substrate BS and a light-emitting element ED including a light-emitting layer EML disposed on the base substrate BS (S100).

Referring to FIGS. 6A and 7B, the method of manufacturing a display device according to an embodiment of the disclosure may include, after the providing of the light-emitting element ED (S100), forming an inorganic deposition layer INF on the light-emitting element ED (S200).

Referring to FIGS. 6B and 7B, the forming of the inorganic deposition layer INF (S200) may include forming a preliminary inorganic deposition layer P_INF including a first preliminary portion P_P1 and a second preliminary portion P_P2 (S210) and etching at least a portion of a second preliminary upper surface P_US2 and forming an irregular pattern PT (S220). The first preliminary portion P-P1 may include a first preliminary upper surface P-US1 inclined at a first angle θ1 with respect to an upper surface B-US of the base substrate BS, and the second preliminary portion P-P2 may include the second preliminary upper surface P_US2 substantially parallel to the upper surface B-US of the base substrate BS.

Referring to FIGS. 7A and 7B, in the forming of the preliminary inorganic deposition layer P_INF, the preliminary inorganic deposition layer P_INF may include the first preliminary portion P_P1 and the second preliminary portion P_P2. The first preliminary portion P_P1 may include the first preliminary upper surface P_US1, and the second preliminary portion P_P2 may include the second preliminary upper surface P_US2. The first preliminary upper surface P_US1 may be inclined at the first angle θ1 with respect to the upper surface B_US of the base substrate BS, and the second preliminary upper surface P_US2 may be substantially parallel to the upper surface of the base substrate BS. The first angle θ1 may be in a range of about 60 degrees to about 90 degrees, and the first preliminary upper surface P_US1 may be inclined at the first angle θ1 with respect to the upper surface B_US of the base substrate BS. The first preliminary portion P_P1 including the first preliminary upper surface P_US1 may be formed on a side surface of a pixel-defining film PDL.

In the forming of the preliminary inorganic deposition layer P_INF, the first preliminary portion P_P1 and the second preliminary portion P_P2 may be formed of a same material through a same process. Accordingly, a thickness d11 of the first preliminary portion P_P1 and a thickness d12 of the second preliminary portion P_P2 may be substantially the same. The thickness d11 of the first preliminary portion P_P1 and the thickness d12 of the second preliminary portion P_P2 may be in a range of about 50 Å to about 200 Å.

The forming of the preliminary inorganic deposition layer P_INF may include a process of depositing an inorganic material having a refractive index of about 1.0 or greater and a light absorption coefficient of about 0.5 or greater. The forming of the preliminary inorganic deposition layer P_INF may include a process of depositing an inorganic material having a melting point of about 1,000° C. or smaller. The preliminary inorganic deposition layer P_INF may overlap (e.g., entirely overlap) the light-emitting element ED in a plan view. The forming of the preliminary inorganic deposition layer P_INF may include performing a thermal evaporation process. The forming of the preliminary inorganic deposition layer P_INF may be constituted of a thermal evaporation process.

The forming of the irregular pattern PT may include etching at least a portion of the second preliminary portion P_P2. The forming of the irregular pattern PT may include etching at least a portion of the second preliminary upper surface P_US2. The etching of at least a portion of the second preliminary upper surface P_US2 may include performing any one among a wet etching process, a dry etching process, an ion milling process, and a spacer patterning technology (SPT) process. However, the disclosure is not limited thereto.

The forming of the irregular pattern PT may include etching at least a portion of the second preliminary upper surface P_US2 and forming a second portion P2. The at least a portion of the second preliminary upper surface P_US2 may be etched, and a thickness of the second portion P2 may be in a range of about 40 Å to about 100 Å.

Particles (not illustrated) of the second preliminary portion P_P2 may be generated during the etching of the second preliminary upper surface P_US2. The generated particles (not illustrated) may arrive at the first preliminary upper surface P_US1. The particles (not illustrated) may be attached onto the first preliminary upper surface P_US1 of the first preliminary portion P_P1. Thus, a first portion P1 may be formed. Accordingly, the first portion P1 onto which the particles (not illustrated) are additionally attached may have a greater thickness (e.g., a greater thickness value) than the first preliminary portion P_P1. Since the at least a portion of the second preliminary upper surface P_US2 is etched, a thickness of the first portion P1 may become greater than a thickness of the first preliminary portion P_P1, and a thickness of the second portion P2 may become smaller than a thickness of the second preliminary portion P_P2. Accordingly, a thickness of the first portion P1 may be greater than a thickness of the second portion P2.

The forming of the irregular pattern PT may include the etching of the second preliminary upper surface P_US2 and may not include etching the first preliminary upper surface P_US1. The irregular pattern PT may be formed only on an upper surface of the second portion P2 and may not be formed on an upper surface of the first portion P1. Accordingly, a surface roughness of the upper surface of the second portion P2 may be higher than a surface roughness of the upper surface of the first portion P1.

According to an embodiment of the disclosure, a display device may include a portion having a non-uniform thickness in an inorganic deposition layer. Accordingly, light efficiency of a display device including a light emitting element may be improved and external light reflection may be reduced.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising a display panel, the display panel including:
a light-emitting element disposed on a base substrate and including a light-emitting layer;
an inorganic deposition layer disposed on the light-emitting element; and
an encapsulation layer disposed on the inorganic deposition layer, wherein
the inorganic deposition layer includes:
a first portion including a first upper surface inclined at a first angle with respect to an upper surface of the base substrate; and
a second portion including a second upper surface substantially parallel to the upper surface of the base substrate, and
a first thickness of the first portion is greater than a second thickness of the second portion.

2. The display device of claim 1, wherein the first angle is in a range of about 60 degrees to about 90 degrees.

3. The display device of claim 1, wherein a surface roughness of the first upper surface is smaller than a surface roughness of the second upper surface.

4. The display device of claim 1, wherein an irregular pattern is defined on the second upper surface.

5. The display device of claim 1, wherein
the display panel further comprises:
a pixel-defining film disposed on the base substrate and having a pixel opening, and
the light-emitting layer is disposed in the pixel opening.

6. The display device of claim 5, wherein
the pixel-defining film comprises a side surface defining the pixel opening,
the side surface of the pixel-defining film is inclined at a second angle with respect to the upper surface of the base substrate, and
the second angle is substantially the same as the first angle.

7. The display device of claim 1, wherein the inorganic deposition layer comprises an inorganic material having a refractive index of about 1.0 or greater and a light absorption coefficient of about 0.5 or greater.

8. The display device of claim 1, wherein the inorganic deposition layer comprises at least one selected from the group consisting of bismuth (Bi) and ytterbium (Yb).

9. The display device of claim 1, wherein a difference between the first thickness and the second thickness is in a range of about 5 Å to about 50 Å.

10. The display device of claim 1, wherein the first thickness is in a range of about 50 Å to about 200 Å.

11. The display device of claim 1, wherein the second thickness is in a range of about 40 Å to about 100 Å.

12. The display device of claim 1, wherein the encapsulation layer is entirely in contact with the first upper surface and the second upper surface.

13. The display device of claim 1, wherein
the light-emitting element further comprises:
a first electrode disposed on the base substrate;
a second electrode spaced apart from the first electrode;
a hole transport region disposed between the first electrode and the light-emitting layer;
an electron transport region disposed between the second electrode and the light-emitting layer; and
a capping layer disposed on the second electrode,
the light-emitting layer is disposed between the first electrode and the second electrode, and
the inorganic deposition layer is directly disposed on the capping layer.

14. The display device of claim 1, further comprising:
a light control layer disposed on the display panel and including at least one of a dye and a pigment; and
a sensor layer disposed between the display panel and the light control layer.

15. A display device, comprising:
a display panel; and
a light control layer disposed on the display panel and including at least one of a dye and a pigment, wherein
the display panel includes:
a light-emitting element disposed on a base substrate and including a light-emitting layer;
an inorganic deposition layer disposed on the light-emitting element and including:
a partition portion; and
a flat portion adjacent to the partition portion; and
an encapsulation layer being entirely in contact with a first upper surface of the partition portion and a second upper surface of the flat portion,
the first upper surface is inclined at a first angle with respect to an upper surface of the base substrate,
the second upper surface is substantially parallel to the upper surface of the base substrate, and
a surface roughness of the first upper surface is smaller than a surface roughness of the second upper surface.

16. A method of manufacturing a display device, the method comprising:
providing a base substrate and a light-emitting element including a light-emitting layer disposed on the base substrate;
forming, on the light-emitting element, an inorganic deposition layer including an inorganic material; and
forming an encapsulation layer on the inorganic deposition layer, wherein
the forming of the inorganic deposition layer includes:
forming a preliminary inorganic deposition layer including:
a first preliminary portion including a first preliminary upper surface having a first angle with respect to an upper surface of the base substrate; and
a second preliminary portion including a second preliminary upper surface substantially parallel to the upper surface of the base substrate, and
forming an irregular pattern by etching at least a portion of the second preliminary upper surface.

17. The method of claim 16, wherein the first angle is in a range of about 60 degrees to about 90 degrees.

18. The method of claim 16, wherein the forming of the preliminary inorganic deposition layer comprises performing a thermal evaporation process.

19. The method of claim 16, wherein the forming of the irregular pattern comprises performing any one among a wet etching process, a dry etching process, and an ion milling process.

20. The method of claim 16, wherein a thickness of the first preliminary portion and a thickness of the second preliminary portion are substantially the same.
